(19) United States
(12) Patent Application Publication
(10) Pub. No.: US 2017/0054077 A1
(43) Pub. Date: Feb. 23, 2017

(54) CRYSTALLIZATION OF ADDITIVES AT P/N JUNCTIONS OF BULK-HETEROJUNCTION PHOTOACTIVE LAYERS

(71) Applicant: SABIC Global Technologies B.V., Amsterdam (NL)

(72) Inventors: Timothy P. Bender, Toronto (CA); Benoit H. Lessard, Ottawa (CA); Jeremy Dang, Toronto (ON)

(21) Appl. No.: 15/305,825

(22) PCT Filed: Apr. 27, 2015
(86) PCT No.: PCT/IB2015/053063

§ 371 Date: Oct. 21, 2016

Related U.S. Application Data
(60) Provisional application No. 61/989,970, filed on May 7, 2014.

(51) Int. Cl. H01L 51/00; C08K 5/56

(52) U.S. Cl. CPC H01L 51/0028; H01L 51/002; H01L 51/0007; H01L 51/0078; H01L 51/0094; H01L 51/0047; H01L 51/0036; C08K 5/56; H01L 51/4253

(57) ABSTRACT

Disclosed is a method for making a bulk-heterojunction photoactive layer, positioning an additive at an interface of a bulk-heterojunction photoactive layer, or enhancing the efficiency of a bulk-heterojunction photoactive layer, the method comprising obtaining a mixture comprising a solvent, an electron donor material, an electron acceptable material, and an additive solubilized in the solvent, wherein the additive has a high (negative) enthalpy of crystalization (ΔH_{cryst}), and forming a bulk-heterojunction photoactive layer from the mixture, wherein crystals of the additive are formed and positioned at an interface between the electron donor material and the electron acceptor material of the bulk-heterojunction photoactive layer.

### CROSS REFERENCE TO RELATED APPLICATIONS

This application claims the benefit of U.S. Provisional Application No. 61/989,970 titled “CRYSTALLIZATION OF ADDITIVES AT P/N JUNCTIONS OF BULK-HETEROJUNCTION PHOTOACTIVE LAYERS”, filed May 7, 2014. The entire contents of the referenced patent application are incorporated into the present application by reference.

### BACKGROUND OF THE INVENTION

A. Field of the Invention

The invention generally concerns the use of additives in bulk-heterojunction photoactive layers. In particular, a new discovery has been made that allows for increased placement or localization of additives at the donor/acceptor interfaces (or p-n junctions) of bulk-heterojunction photoactive layers. This can result in enhanced efficiency of these layers.

B. Description of Related Art

Over the last decade the interest in organic photovoltaic devices (OPVs) has grown exponentially due to the numerous advances in the field in addition to the ever pressing need for alternative energy sources. While promising results have been reported for bilayered or planar heterojunction OPV device structures, the majority of the literature is focused on the fabrication of a bulk heterojunction (BHJ) OPVs that utilize the blending of a mixture of donor-acceptor polymers and/or small molecules which mutually phase separate when deposited as a single functional layer. Recently, OPVs based on BHJ configurations have been reported to have power conversion efficiencies (n_{eff}) approaching 9% using a variety of unique synthetic polymers.

For instance, P3HT:PC₆₁BM (poly(3-hexylthiophene):phenyl-C₆₁-butyric acid methyl ester) is arguably the most studied donor-acceptor pair of materials used as the active layer in a BHJ OPV, with countless publications showing these devices having η_{eff} ranging between 2-5% (Dang, et al., Advanced Materials. 2011, 23:3597-3602). Several factors such as compound purity, annealing temperature and time, the use of a low boiling solvent and additives and the overall ratio of P3HT to PC₆₁BM have all been identified as contributors to this variation in efficiency (Dang, et al., 2011; Dang, et al., Chemical Reviews, 2013, 113:3734-3765). It is also accepted that the energy levels associated with P3HT and PC₆₁BM are not ideal and that increased efficiency could or can result from modifying the energy levels of the frontier molecular orbitals of P3HT or PC₆₁BM (Blouin, et al., J. Am. Chem. Soc. 2008, 130:732-742; Boudreault, et al., Chem. Mater., 2011, 23:456-469).

In place of altering the energy levels of the frontier orbitals, another method which has been shown to increase P3HT:PC₆₁BM BHJ OPV device efficiency is to incorporate a third component (i.e., an additive), either a small molecule or polymer, to act as a second donor or acceptor. This configuration is referred to as a cascade BHJ whereby the increase in device η_{eff} is achieved by increasing the light absorption, exciton dissociation or even hole or electron transfer between the P3HT and PC₆₁BM or PC₇₁BM domains (Chen, et al., ChemSusChem. 2013, 6:20-35; Khlyabich, et al., Journal of the American Chemical Society. 2012, 134:9074-9077; Khlyabich, et al., Journal of the American Chemical Society. 2011, 133:14534-14537). For example, Chen et al., 2013 utilized an ambipolar poly[2,3-bis(thiophen-2-yl)-acrylonitrile-9,9′-dioctyl-fluorene] polymer as an additive in a P3HT:PC₆₁BM cascade BHJ OPV device (Chen, et al., 2011). The authors noted up to a 30% increase in η_{eff} when adding as little as ˜2.5 wt % of the polymer with respect to P3HT:PC₆₁BM. Also, Honda et al. explored the use of metal-containing phthalocyanines for the formation of a P3HT:PC₆₁BM cascade BHJ (Honda, et al., ACS Applied Materials & Interfaces, 2009, 1:804-810, and Honda, et al., Chem. Commun. 2010, 46:6596-6598). An increase of up to 20% in n_{eff} was noted when bis(tri-n-hexylsilyl oxide) silicon phthalocyanine ((3HS)₂—SiPc) as added to the P3HT:PC₆₁BM BHJ OPV device (Honda, et al., 2009).

One of the problems of using additives in BHJ photoactive layers, however, is that they have a limited effect or ceiling on improving the efficiency of a given BHJ layer. Additionally, there are not many additives that are currently available that provide improved efficiency such as those discussed in the above paragraph.

### SUMMARY OF THE INVENTION

A solution has been discovered to increase the efficacy of additives used in BHJ photoactive layers. In particular, the discovery is premised on placing or localizing additives at the p-n junctions of BHJ photoactive layers. This allows additives to more readily serve their purpose of enhancing the efficiency of BHJ photoactive layers. Without wishing to be bound by theory, it is believed that crystallizing additives during the process of making BHJ photoactive layers aids in placing or localizing the additives at interfaces between the electron donor and acceptor materials. The processes of the present invention provide for a way to increase the presence of an additive in a BHJ photoactive layer at the p-n junctions. The benefits of such placement results in an increase in, or enhancement of, the overall efficiency of such BHJ layers. The processes further allow for the use of known additives that were once thought to have limited value or to select additives based on processing conditions that favor crystallization. Further, selection of additives that have high (negative) enthalpies of crystalization (ΔH_{cryst}) can be advantageous in the context of the present invention.

In one embodiment of the present invention, there is disclosed a method for making a bulk-heterojunction photoactive layer or a method for positioning an additive at an interface of a bulk-heterojunction photoactive layer or a method for enhancing the efficiency of a bulk-heterojunction photoactive layer. Each of these methods can include: (1) obtaining a mixture comprising a solvent, an electron donor material, an electron acceptable material, and an additive solubilized in the solvent, wherein the additive has a high (negative) enthalpy of crystalization (ΔH_{cryst}), and (2) forming a bulk-heterojunction photoactive layer from the mixture, wherein crystals of the additive are formed and positioned at an interface between the electron donor material and the electron acceptor material of the bulk-heterojunction photoactive layer. The additive used can be selected based on its crystallization tendency. For example, additives that have a high (negative) enthalpy of crystalization (ΔH_{cryst}) (i.e., at least 1 μJ mol⁻¹) can be used in the context of the present invention. In more particular embodiments, the enthalpy of crystallization (ΔH_{cryst}) can range from 1 μJ mol⁻¹ to 100 J mol⁻¹. In still more particular embodiments, the enthalpy of crystallization (ΔH_{cryst}) can be at least 2 μJ mol⁻¹, at least 3 μJ mol⁻¹, at least 4 μJ mol⁻¹, at least 5 μJ mol⁻¹ , at least 6 μJ mol⁻¹, at least 7 μJ mol⁻¹, at least 8 μJ mol⁻¹, at least 9 μJ mol⁻¹, at least 10 μJ mol⁻¹ , at least 11 μJ mol⁻¹, at least 12 μJ mol⁻¹, at least 13 μJ mol⁻¹, at least 14 μJ mol⁻¹ , at least 15 μJ mol⁻¹, at least 16 μJ mol⁻¹, at least 17 μJ mol⁻¹, at least 18 μJ mol⁻¹ , at least 19 μJ mol⁻¹, at least 20 μJ mol⁻¹, at least 25 μJ mol⁻¹, at least 30 μJ mol⁻¹, at least 35 μJ mol⁻¹, at least 40 μJ mol⁻¹ , at least 45 μJ mol⁻¹, at least 50 μJ mol⁻¹, at least 60 μJ mol⁻¹, at least 70 μJ mol⁻¹, at least 80 μJ mol⁻¹ , at least 90 μJ mol⁻¹, at least 100 μJ mol⁻¹, at least 150 μJ mol⁻¹, at least 200 μJ mol⁻¹, at least 250 μJ mol⁻¹ , at least 300 μJ mol⁻¹, at least 350 μJ mol⁻¹, at least 400 μJ mol⁻¹, at least 450 μJ mol⁻¹, at least 500 μJ mol⁻¹ , at least 550 μJ mol⁻¹, at least 600 μJ mol⁻¹, at least 650 μJ mol⁻¹, at least 700 μJ mol⁻¹, at least 800 μJ mol⁻¹ , at least 850 μJ mol⁻¹, at least 900 μJ mol⁻¹, at least 950 μJ mol⁻¹, at least 1 J mol⁻¹, at least 2 J mol⁻¹ , at least 3 J mol⁻¹, at least 4 J mol ⁻¹at least 5 J mol⁻¹, at least 6 J mol⁻¹, at least 7 J mol⁻¹, at least 8 J mol⁻¹, at least 9 J mol⁻¹ , at least 10 J mol⁻¹, at least 15 J mol⁻¹, at least 20 J mol⁻¹, at least 25 J mol⁻¹, at least 30 J mol⁻¹ , at least 35 J mol⁻¹, at least 40 J mol⁻¹, at least 45 J mol⁻¹, at least 50 J mol⁻¹, at least 55 J mol⁻¹ , at least 60 J mol⁻¹, at least 65 J mol⁻¹, at least 70 J mol⁻¹, at least 80 J mol⁻¹, at least 85 J mol⁻¹ , at least 90 J mol⁻¹, at least 95 J mol⁻¹, up to 100 J mol⁻¹, or any range therein. In still other embodiments, enthalpy of crystallization (ΔH_{cryst}) can be greater than 100 J mol⁻¹ (e.g., 110, 120, 130, 140, 150, 160, 170, 180, 190, 200, 300, 400, 500, 600, 700, 800, 900, or more J mol⁻¹, or any range therein). All types of additives that are currently used in BHJ layers or that may later be discovered can be used in the context of the present invention. Efficiency increase might be a result of a number of factors including improved morphology of any one of the nanoscaled regions present in the bulk-heterojunction photoactive layer and enhanced crystallization of the electro/photoactive ternary additive. A few non-limiting examples of additives that can be used include alkanedithiols (e.g., 1,6-dithiolhexane; 1,8-dithioloctane; 1,10-dithioldecane; etc.), alkyldihalides (e.g, 1,6-dichlorohexane; 1,6-dibromohexane; 1,8-dichlorooctane; 1,8-dibromooctane; 1,8-diiodooctane, 1,8-dichlorodecane; 1,8-dibromodecane; 1,8-diiododecane; etc.), alkyldinitriles (e.g, octadinitrile; decanedinitrile; dodecanedinitrile; etc.), phthalocyanines, derivatives thereof (i.e., substituted compounds), or any combinations or mixtures thereof in more preferred aspects, the additive can be an alkanedithiol or a phthalocyanine or combination thereof. In a particular aspect, the additive can be bis(tri-n-hexylsilyl oxide) germanium phthalocyanine. The additive (which can include single or mixtures and combinations of additives) can be solubilized in the solvent up to its saturation point or can be supersaturated in the solvent. In some instances, the mixture can further include a nucleation agent to promote crystallization of the additive. In some particular instances, the mixture can be heated and cooled or dried under conditions that promote crystallization of the additive (e.g., slower cooling conditions using a vacuum oven or a hot plate can be used). Still further, non-solvents or anti-solvents can be added during the process to promote crystallization of the additive. The electron acceptor and donor materials of the present invention can be those currently known in the art as well as those that may later be discovered. Some non-limiting examples of electron donor material include poly(trihexylthiopene) (P3HT) or Poly[2-methoxy-5-(2-ethylhexyloxy)-1,4-phenylenevinylene], or a combination thereof. Some non-limiting examples of electron acceptor material include [6,6] phenyl-C₆₁-butyric acid methyl ester (PC₆₁BM), [6,6] phenyl-C₇₁-butyric acid methyl ester (PC₇₁BM), or 1′,1″,4′,4″-tetrahydro-di [1,4] methanonaphthaleno [1,2:2′,3′,56,60:2″,3″] [5,6] fullerene-C₆₀ (ICBA), or any combination thereof. In one particular aspect of the present invention, the donor material and the acceptor material is a P3HT:PC₆₁BM blend. Non-limiting examples of solvents that can be used in the context of the present invention include chlorobenzene, chloroform, dichlorobenzene, duchloromethane, xylenes, tetrahydronaphthalene, toluene, benzene, quinolone, m-cresol, 1,2,4-trimethylbenzene, methylnaphthalene, or di-methylnaphthalene, or any combination thereof. The bulk-heterojunction photoactive layer can be formed on a substrate. The mixture can be disposed onto a surface of the substrate (e.g., by doctor blade coating, spin coating, meniscus coating, transfer printing, ink jet printing, offset printing or screen printing process). The substrate can be transparent, translucent, or reflective. In certain instances, the additive is not bis(tri-n-hexylsilyl oxide) silicon phthalocyanine. The power conversion efficiency (n_{eff}) of the bulk-heterojunction photoactive can be enhanced by the crystallization positioning of the additive at the interface between the electron donor material and the electron acceptor material. The short-circuit current (J_{SC}) of the bulk-heterojunction photoactive can be enhanced by the crystallization positioning of the additive at the interface between the electron donor material and the electron acceptor material.

The bulk-heterojunction photoactive layers of the present invention can be used in electronic applications. These layers can be used in an active layer of an electronic device. The active layer can be an organic or hybrid semiconducting or conducting layer. The device can include a substrate, the photoactive layer, and at least two electrodes, one of which is transparent. At least a portion or all of the photoactive layer is disposed between said electrodes. The transparent electrode can be a cathode and the other electrode can be an anode. Alternatively, the transparent electrode can be an anode and the other electrode can be a cathode. In some instances both of the aforementioned electrodes can be transparent. In other instances, one of the electrodes can be transparent while the other is non-transparent (e.g., opaque) or reflective, such that it can reflect electromagnetic radiation such as ultraviolet light or visible light or sun light. Still further, the substrate can be opaque, reflective, or transparent. In particular instances, the electronic device can be a photovoltaic cell or can include a photovoltaic cell. Said cell may not include an electrolyte. The photovoltaic cell can be included in an organic electronic device. Examples of such devices include organic light-emitting diodes (OLEDs) (e.g., polymeric organic light-emitting diodes (PLEDs), small-molecule organic light-emitting diodes (SM-OLEDs), organic integrated circuits (O-ICs), organic field effect transistors (OFETs), organic thin film transistors (OTFTs), organic solar cell (O-SCs), and organic laser diodes (O-lasers).

Also disclosed in the context of the present invention are embodiments 1 to 28. Embodiment 1 is a method for making a bulk-heterojunction photoactive layer, positioning an additive at an interface of a bulk-heterojunction photoactive layer, or enhancing the efficiency of a bulk-heterojunction photoactive layer, the method comprising: (1) obtaining a mixture comprising a solvent, an electron donor material, an electron acceptable material, and an additive solubilized in the solvent, wherein the additive has a high (negative) enthalpy of crystalization (ΔH_{cryst}); and (2) forming a bulk-heterojunction photoactive layer from the mixture, wherein crystals of the additive are formed and positioned at an interface between the electron donor material and the electron acceptor material of the bulk-heterojunction photoactive layer. Embodiment 2 is the method of embodiment 1, wherein the additive used is selected based on its crystallization tendency. Embodiment 3 is the method of embodiment 1, wherein the additive in step (1) is solubilized in the solvent up to its saturation point or is supersaturated in the solvent. Embodiment 4 is the method of any one of embodiments 1 to 3, wherein the mixture further comprises a nucleation agent to promote crystallization of the additive during step (2). Embodiment 5 is the method of any one of embodiments 1 to 4, wherein the mixture in step (1) is heated and the mixture in step (2) is cooled or dried under conditions that promote crystallization of the additive. Embodiment 6 is the method of any one of embodiments 1 to 6, wherein a non-solvent is added to the mixture in step 2 to promote crystallization of the additive. Embodiment 7 is the method of any one of embodiments 1 to 6, wherein the donor material and the acceptor material is a P3HT:PC₆₁BM blend. Embodiment 8 is the method of any one of embodiments 1 to 7, wherein the electron donor material is poly(trihexylthiopene) (P3HT) or Poly[2-methoxy-5-(2-ethylhexyloxy)-1,4-phenylenevinylene], or a combination thereof. Embodiment 9 is the method of any one of embodiments 1 to 8, wherein the electron acceptor material is [6,6] phenyl-C₆₁-butyric acid methyl ester (PC₆₁BM), [6,6] phenyl-C₇₁-butyric acid methyl ester (PC₇₁BM), or 1′,1″,4′,4″-tetrahydro-di [1,4] methanonaphthaleno [1,2:2′,3′,56,60:2″,3″] [5,6] fullerene-C₆₀ (ICBA), or any combination thereof. Embodiment 10 is the method of any one of embodiments 1 to 9, wherein the additive is alkanedithiol or bis(tri-n-hexylsilyl oxide) germanium phthalocyanine or a combination thereof. Embodiment 11 is the method of any one of embodiments 1 to 10, wherein the solvent is chlorobenzene, chloroform, dichlorobenzene, duchloromethane, xylenes, tetrahydronaphthalene, toluene, benzene, quinolone, m-cresol, 1,2,4-trimethylbenzene, methylnaphthalene, or di-methylnaphthalene, or any combination thereof. Embodiment 12 is the method of any one of embodiments 1 to 11, wherein the bulk-heterojunction photoactive layer is formed on a substrate. Embodiment 13 is the method of embodiment 12, wherein the mixture from step (1) is disposed onto a surface of the substrate. Embodiment 14 is the method of embodiment 13, wherein the mixture is disposed by doctor blade coating, spin coating, meniscus coating, transfer printing, ink jet printing, offset printing or screen printing process. Embodiment 15 is the method of any one of embodiments 12 to 14, wherein the substrate is an electrode. Embodiment 16 is the method of embodiment 15, wherein the electrode is transparent or translucent. Embodiment 17 is the method of embodiment 15, wherein the electrode is reflective. Embodiment 18 is the method of embodiment 17, wherein the additive is not bis(tri-n-hexylsilyl oxide) silicon phthalocyanine. Embodiment 19 is the method of any one of embodiments 1 to 18, wherein the power conversion efficiency (n_{eff}) of the bulk-heterojunction photoactive is enhanced by the crystallization positioning of the additive at the interface between the electron donor material and the electron acceptor material. Embodiment 20 is the method of any one of embodiments 1 to 19, wherein the short-circuit current (J_{SC}) of the bulk-heterojunction photoactive is enhanced by the crystallization positioning of the additive at the interface between the electron donor material and the electron acceptor material. Embodiment 21 is a photovoltaic cell comprising a bulk-heterojunction photoactive layer prepared by the process of any one of embodiments 1 to 20. Embodiment 22 is the photovoltaic cell of embodiment 21, comprising a transparent substrate, a transparent electrode, the bulk-heterojunction photo-active layer, and a second electrode, wherein the photoactive layer is disposed between the transparent electrode and the second electrode. Embodiment 23 is the photovoltaic cell of embodiment 22, wherein the transparent electrode is a cathode and the second electrode is an anode. Embodiment 24 is the photovoltaic cell of embodiment 22, wherein the transparent electrode is an anode and the second electrode is a cathode. Embodiment 25 is the photovoltaic cell of any one embodiments 21 to 24, wherein the second electrode is not transparent. Embodiment 26 is the photovoltaic cell of any one of embodiments 21 to 25, wherein the photovoltaic cell is comprised in an organic electronic device. Embodiment 27 is a bulk-heterojunction photoactive layer prepared by the process of any one of embodiments 1 to 20. Embodiment 28 is the bulk-heterojunction photoactive layer of embodiment 27, comprised in a photovoltaic cell.

“Additive” in the context of the present invention refers to materials (e.g., compounds, oligomers, polymers, etc.) that can increase the efficiency or performance of a bulk-heterojunction photoactive layer.

The term “about” or “approximately” are defined as being close to as understood by one of ordinary skill in the art, and in one non-limiting embodiment the terms are defined to be within 10%, preferably within 5%, more preferably within 1%, and most preferably within 0.5%.

The use of the word “a” or “an” when used in conjunction with the term “comprising” in the claims or the specification may mean “one,” but it is also consistent with the meaning of “one or more,” “at least one,” and “one or more than one.”

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The processes of making bulk-heterojunction photoactive layers, photovoltaic cells, and the organic electronic devices of the present invention can “comprise,” “consist essentially of,” or “consist of” particular additives, ingredients, components, compounds, compositions, etc. disclosed throughout the specification. With respect to the transitional phase “consisting essentially of,” in one non-limiting aspect, a basic and novel characteristic of the aforesaid processes is the ability to achieve crystallization of additives at an interface between the electron donor material and the electron acceptor material of a bulk-heterojunction photoactive layer.

Other objects, features and advantages of the present invention will become apparent from the following figures, detailed description, and examples. It should be understood, however, that the figures, detailed description, and examples, while indicating specific embodiments of the invention, are given by way of illustration only and are not meant to be limiting. Additionally, it is contemplated that changes and modifications within the spirit and scope of the invention will become apparent to those skilled in the art from this detailed description.

### BRIEF DESCRIPTION OF THE DRAWINGS

FIG. 1: Illustration of a bulk-heterojunction photoactive layer of the present invention.

FIG. 2: Illustration of an organic photovoltaic cell incorporating a bulk-heterojunction photoactive layer of the present invention.

FIG. 3: Energy level diagram and chemical structure of poly(3-hexylthiophene) (P3HT), bis(tri-n-hexylsilyl oxide) silicon phthalocyanine ((3HS)₂—SiPc), bis(3-pentadecylphenoxy)-silicon phthalocyanine ((PDP)₂—SiPc), tri-n-hexylsilyl oxide boron subphthalocyanine (3HS—BsubPc), 3-pentadecylphenoxy boron subphthalocyanine (PDP—BsubPc). 3-methylphenoxy boron subphthalocyanine (3MP—BsubPc), pentafluorophenoxy boron subphthalocyanine (F₅—BsubPc), bis(tri-n-hexylsilyl oxide) germanium phthalocyanine ((3HS)₂—GePc) and phenyl-C₆₁-butyric acid methyl ester (PC₆₁BM).

FIG. 4A: External quantum efficiency (EQE) versus wavelength plots for the P3HT:PC₆₁BM (1.0:0.8, mass ratio) and P3HT:PC₆₁BM:X (1.0:0.8:Y), where X=bis(tri-n-hexylsilyl oxide) silicon phthalocyanine ((3HS)₂—SiPc, 1), tri-n-hexylsilyl oxide boron subphtahlocyanine (3HS—BsubPc) and bis(tri-n-hexylsilyl oxide) germanium phthalocyanine ((3HS)₂—GePc) and where Y=0.2 (10.6 wt %), 0.1 (5.3 wt %) or 0.07 (3.7 wt %). Standard P3HT:PC₆₁BM BHJ solar device data (no tertiary additive) is shown with error bars to illustrate the space occupied by standard devices.

FIG. 4B: Current versus voltage (IV) plots for the P3HT:PC₆₁BM (1.0:0.8, mass ratio) and P3HT:PC₆₁BM:X (1.0:0.8:Y), where X=bis(tri-n-hexylsilyl oxide) silicon phthalocyanine ((3E15)₂—SiPc, 1), tri-n-hexylsilyl oxide boron subphtahlocyanine (3HS—BsubPc) and bis(tri-n-hexylsilyl oxide) germanium phthalocyanine ((3HS)₂—GePc) and where Y=0.2 (10.6 wt %), 0.1 (5.3 wt %) or 0.07 (3.7 wt %). Standard P3HT:PC₆₁BM BHJ solar device data (no tertiary additive) is shown with error bars to illustrate the space occupied by standard devices.

FIG. 5A: Electrochemical spectra for bis(tri-n-hexylsilyl oxide) silicon phthalocyanine ((3HS)₂—SiPc).

FIG. 5B: Electochemical spectra for bis(tri-n-hexylsilyl oxide) germanium phthalocyanine ((3HS)₂—GePc), C) tri-n-hexylsilyl oxide boron subphthalocyanine (3HS—BsubPc), and D) bis(3-pentadecylphenoxy)-silicon phthalocyanine ((PDP)₂—SiPc).

FIG. 5C: Electrochemical spectra for tri-n-hexylsilyl oxide boron subphthalocyanine (3HS—BsubPc).

FIG. 5D: Electrochemical spectra for bis(3-pentadecylphenoxy)-silicon phthalocyanine ((PDP)₂—SiPc).

FIG. 6A: External quantum efficiency (EQE) versus wavelength plots for P3HT:PC₆₁BM:PDP—BsubPc (1:0.8:X, where X=0.2 (10.6 wt %), 0.1 (5.3 wt %) and 0.07 (3.7 wt %)) and as active layer in a BHJ OPV device.

FIG. 6B: Current versus voltage (IV) plots for P3HT:PC₆₁BM:PDP—BsubPc (1:0.8:X, where X=0.2 (10.6 wt %), 0.1 (5.3 wt %) and 0.07 (3.7 wt %)) and as active layer in a BHJ OPV device.

FIG. 6C: EQE versus wavelength plots for P3HT:PC₆₁BM:X (where X=to 5.3 wt % addition of 3MP—BsubPc, PDP—BsubPc, F5—BsubPc or both 2.7 wt % of 3MP—BsubPc and 2.7 wt % of F5—BsubPc) as active layer in a BHJ OPV devices. P3HT:PC₆₁BM is the pristine, standard BHJ OPV device (no tertiary additive) with error bars which arise from the standard deviation of all P3HT:PC₆₁BM pristine BHJ OPV device.

FIG. 6D: IV plots for P3HT:PC₆₁BM:X (where X=to 5.3 wt % addition of 3MP—BsubPc, PDP—BsubPc, F5—BsubPc or both 2.7 wt % of 3MP—BsubPc and 2.7 wt % of F5—BsubPc) as active layer in a BHJ OPV devices. P3HT:PC₆₁BM is the pristine, standard BHJ OPV device (no tertiary additive) with error bars which arise from the standard deviation of all P3HT:PC₆₁BM pristine BHJ OPV device.

FIG. 7A: Ellipsoid plot (50% probability) showing the structure and atom number scheme of (3HS)₂—SiPc (CCDC deposition number: 988974).

FIGS. 7B and 7C: Crystal structure arrangements of multiple (PDP)₂—SiPc molecules. (3HS)₂—SiPc single crystals were grown by slow evaporation from dichloromethane and characterized by x-ray crystallography. The cube represents the unit cell.

FIG. 8A: External quantum efficiency (EQE) versus wavelength for P3HT:PC₆₁BM:(PDP)₂—SiPc (1:0.8:X, where X=0.2 (10.6 wt %), 0.1 (5.3 wt %) and 0.07 (3.7 wt %)) and as active layer in a BHJ OPV device. P3HT:PC₆₁BM is the pristine, standard BHJ OPV device (no tertiary additive) with error bars which arise from the standard deviation of all P3HT:PC₆₁BM pristine BHJ OPV devices as outlined in the “Baseline P3HT:PC₆₁BM BHJ Devices” section.

FIG. 8B: Current versus voltage (IV) plots for P3HT:PC₆₁BM:(PDP)₂—SiPc (1:0.8:X, where X=0.2 (10.6 wt %), 0.1 (5.3 wt %) and 0.07 (3.7 wt %)) and as active layer in a BHJ OPV device. P3HT:PC₆₁BM is the pristine, standard BHJ OPV device (no tertiary additive) with error bars which arise from the standard deviation of all P3HT:PC₆₁BM pristine BHJ OPV devices as outlined in the “Baseline P3HT:PC₆₁BM BHJ Devices” section.

FIG. 9A: Ellipsoid plot (50% probability) showing the structure and atom number scheme of (PDP)₂—SiPc (CCDC deposition number: 988976).

FIGS. 9B and 9C: Crystal structure arrangements of multiple (PDP)₂—SiPc molecules. (PDP)₂—SiPc single crystals were grown by slow evaporation from dichloromethane and characterized by x-ray crystallography. The cube represents the unit cell.

### DETAILED DESCRIPTION OF THE INVENTION

The present invention provides for a way to increase the efficiency or performance (e.g., increased J_{sc} or η_{eff} or both) of bulk-heterojunction photoactive layers. This is done by positioning additives at the p-n junctions of such photoactive layers via crystallization of said additives. By comparison, and as illustrated in non-limiting aspects in the Examples, additives that do not crystallize at the p-n junctions (or are more difficult to crystallize) in such layers result in lower efficiency and performance of the layers. In preferred aspects, additives having high (negative) enthalpies of crystalization (ΔH_{cryst}) are used, as the processing steps to achieve crystallization can be minimized. However, additional steps can be used to help crystallize additives that have either high (negative) or low (positive) enthalpies of crystallization (e.g., nucleation agent, modifying cooling and drying procedures, etc.). Thus, all types of additives can be used in the context of the present invention.

These and other non-limiting aspects of the present invention are discussed in detail in the following sections.

A. Bulk-Heterojunction Layers and Additive Crystallization

Bulk heterojunction (BHJ) photoactive layers typically utilize the blending of a mixture of electron donor-acceptor polymers, oligomers, or small molecules, or combinations thereof that mutually phase separate when deposited as a single functional layer. The phase separation results in the formation of interfaces or junctions between the electron donor material (i.e., n-type material) and electron acceptor material (i.e., p-type material). All types of donor and acceptor materials can be used in the context of the present invention. By way of example, non-limiting examples of donor materials include P3HT, poly[2-methoxy-5-(3,7-dimethyloctyloxy)-1 ,4-phenylene vinylene] (MDMO-PPV), or poly(2-methoxy-5-(2′-ethyl-hexyloxy)-1, 4-phenylene vinylene) (MEH-PPV), or combinations or blends thereof. Non-limiting examples of electron acceptor materials include PCBMs or [6,6]-phenyl C7i-butyric acid methyl ester (C70-PCBMs). Other materials such as single-walled carbon nanotubes (CNTs) and other n-type polymers can also be used as the acceptor material as well.

All types and kinds of additives can be used in the context of the present invention. However, and in preferred aspects, additives that have high (negative) enthalpies of crystalization (ΔH_{cryst}) can be used to help promote their crystallization. Non-limiting examples of additives that can be used include alkanedithiols (e.g., 1,6-dithiolhexane; 1,8-dithioloctane; 1,10-dithioldecane; etc.), alkyldihalides (e.g, 1,6-dichlorohexane; 1,6-dibromohexane; 1,8-dichlorooctane; 1,8-dibromooctane; 1,8-diiodooctane, 1,8-dichlorodecane; 1,8-dibromodecane; 1,8-diiododecane; etc.), alkyldinitriles (e.g, octadinitrile; decanedinitrile; dodecanedinitrile; etc.), phthalocyanines, derivatives thereof (i.e., substituted compounds), or any combinations or mixtures thereof. Notably, other additives can be used in the context of the present invention, provided that the additives or the processing conditions result in crystallization of the additives and localization of the crystals at the p-n junctions of the bulk-heterojunction photoactive layers of the present invention.

The donor material, acceptor material, and additive can be mixed into a solvent that is capable of solubilizing the additive. The solvent can also be capable of solubilizing the donor and acceptor material or the donor and acceptor material can be dispersed or suspended in the solvent. Non-limiting examples of solvents include unsaturated hydrocarbon-based solvents (such as toluene, xylene, tetralin, decalin, mesitylene, n-butylbenzene, sec-butylbutylbenzene, and tert-butylbenzene), halogenated aromatic hydrocarbon-based solvents (such as chlorobenzene, dichlorobenzene, and trichlorobenzene), halogenated saturated hydrocarbon-based solvents (such as carbon tetrachloride, chloroform, dichloromethane, dichloroethane, chlorobutane, bromobutane, chloropentane, chlorohexane, bromohexane, and chlorocyclohexane), ethers (such as tetrahydrofuran and tetrahydropyran), and polar aprotic solvents (such as dichloromethane (DCM), tetrahydrofuran (THF), ethyl acetate, propyl acetate, butyl acetate, isobutylacetate (and the like), acetone, dimethylformamide (DMF), acetonitrile (MeCN), benzonitrile, nitromethane, dimethyl sulfoxide (DMSO), propylene carbonate, or N-methyl-2-pyrrolidone (NMP), sulfolane (tetramethylene sulfone, 2,3,4,5-tetrahydrothiophene-1,1-dioxide), hexamethylphosphoramide (HMPA), methyl ethyl ketone, methyl isobutyl ketone, acetophenone, benzophenone, or the like), or any combination of said solvents.

The following non-limiting process can be used to make a bulk-heterojunction photoactive layer of the present invention:
(1) prepare a mixture comprising a solvent, an electron donor material, an electron acceptable material, and an additive that is solubilized in the solvent. The amounts, by weight of each of these ingredients, can be varied as desired to achieve a given bulk-heterojunction layer have desired properties. By way of example, the amounts can be 25 to 75 wt. % of the electron donor material, 75 to 25 wt. % of the electron acceptor material, 0.01 to 20 wt. % of the additive, and q.s. with the solvent. The electron donor and acceptor material can be solubilized or dispersed in the solvent. In preferred aspects, the additive is super-saturated in the solvent to help promote crystallization of said additive.
(2) The mixture from (1) can then be deposited by solution-based processes (e.g., spray coating, role-to-role coating, drop casting, dip coating, Mayer rod coating, doctor blade coating, spin coating, meniscus coating, transfer printing, ink jet printing, offset printing, screen printing, gravure printing, flexo printing, dispenser coating, nozzle coating, capillary coating, etc.).
(3) The conditions in (1) and/or (2) can be such that they actively promote crystallization of the additive. The crystallization process typically includes a nucleation event followed by crystal growth. Nucleation occurs when the additive (solute) is solubilized in a solvent and the solute molecules start to gather into clusters, thereby elevating solute concentration in a small region. Once these clusters reach a critical size (which can be promoted by modifying the processing conditions such as temperature, saturation of additive, etc.), the atoms arrange in a defined and periodic manner to create crystals. Without wishing to be bound by theory, it is believed that this crystallization event occurs in close proximity to the p-n junctions being formed by the donor and acceptor materials or that such crystals migrate towards the p-n junctions or during the formation of the p-n junctions. Supersaturation can be the driving force of the crystallization. Thus, the rate of nucleation and growth can be driven by the existing supersaturation of the additive in the solution from (2). Depending upon the conditions, either nucleation or growth may be predominant over the other, and as a result, crystals with different sizes and shapes are obtained. Also, or alternatively, the drying and cooling conditions of the mixture that is deposited on the substrate or electrode can be modified to further promote crystal growth. Still further, a nucleation agent can be included in the mixture from (1) to further enhance or promote crystal growth of the additive.

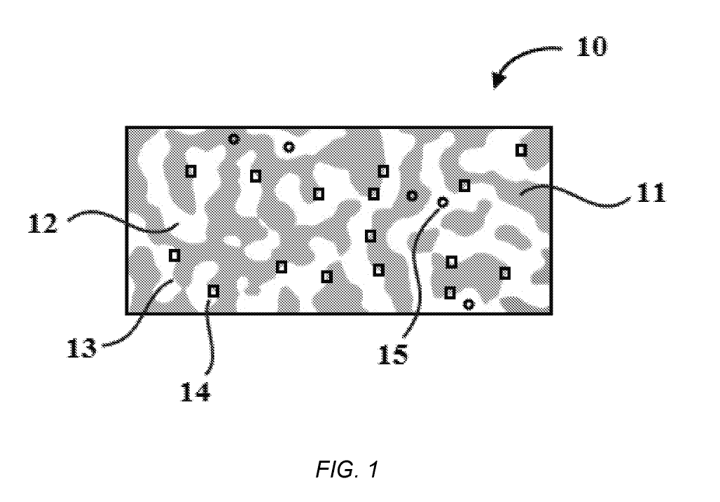

FIG. 1 is a cross-sectional view of a non-limiting example of a bulk-heterojunction photoactive layer (10) of the present invention in which the additive is crystallized and present primarily at p-n junctions of the layer. The donor material (11) and acceptor material (12) form multiple interfaces or p-n junctions (13). During the processing steps discussed above, crystal forms of the additive (14, represented by boxes) are positioned next to or in the p-n junctions (13). In some embodiments, however, some of the additive may be distributed in the donor material (11) or the acceptor material 12, but not at the p-n junction (13). Such additive is represented as small circles (15), which can remain solubilized or can be crystal forms. In preferred embodiments of the present invention the majority of the additive, by weight, is present at/next to the p-n junction in crystalline form. In more preferred embodiments, all of the additive is located at/next to the p-n junction.

B. Organic Photovoltaic Cells

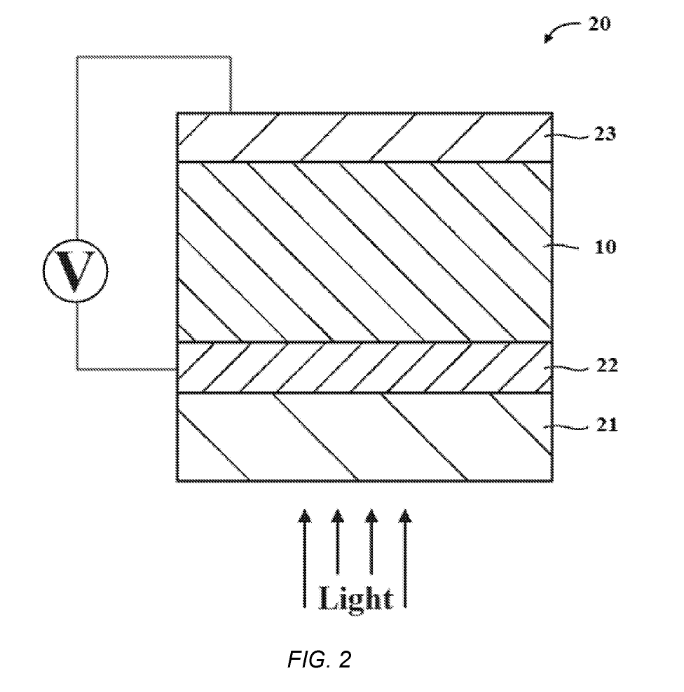

The bulk-heterojunction photoactive layer (10) of the present invention can be used in photovoltaic applications, such as organic photovoltaic cells. FIG. 2 is a cross-sectional view of a non-limiting organic photovoltaic cell of the present invention. The organic photovoltaic cell (20) can include a transparent substrate (21), a front electrode (22), a bulk-heterojunction photoactive layer (10), and a back electrode (23). Additional materials, layers, and coatings (not shown) known to those of ordinary skill in the art can be used with photovoltaic cell (20), some of which are described below.

Generally speaking, the organic photovoltaic cell (20) can convert light into usable energy by: (a) photon absorption to produce excitons; (b) exciton diffusion; (c) charge transfer; and (d) charge separation and transportation to the electrodes. With respect to (a), the excitons are produced by photon absorption by the photoactive layer (10). For (b), the generated excitons diffuse to the p-n junction (13). Then in (c), the charge is transferred to the other constituent of the active layer. For (d), electrons and holes are separated and transported to the electrodes (22) and (13) and are used in a circuit.

The substrate (21) can be used as support. For organic photovoltaic cells, it is typically transparent or translucent, which allows light to efficiently enter the cell. It is typically made from material that is not easily altered or degraded by heat or organic solvents, and as already noted, has excellent optical transparency. Non-limiting examples of such materials include inorganic materials such as alkali-free glass and quartz glass, polymers such as polyethylene, PET, PEN, polyimide, polyamide, polyamidoimide, polycarbonate (e.g., Lexan™, which is a polycarbonate resin offered by SABIC Innovative Plastics), liquid crystal polymer, and cyclic olefin polymer, silicon, and metal.

The front electrode (22) can be used as a cathode or anode depending on the set-up of the circuit. It is stacked on the substrate (21). The front electrode (22) can be made of a transparent or translucent conductive material. Alternatively, the front electrode (22) can be made of opaque or reflective material. Typically, the front electrode (22) is obtained by forming a film using such a material (e.g., vacuum deposition, sputtering, ion-plating, plating, coating, etc.). Non-limiting examples of transparent or translucent conductive material include metal oxide films, metal films, and conductive polymers. Non-limiting examples of metal oxides that can be used to form a film include indium oxide, zinc oxide, tin oxide, and their complexes such as indium stannate (ITO), fluorine-doped tin oxide (FTO), and indium zinc oxide films. Non-limiting examples of metals that can be used to form a film include gold, platinum, silver, and copper. Non-limiting examples of conductive polymers include polyaniline and polythiophene. The thickness of the film for the front electrode (22) is typically between from 30 to 300 nm. If the film thickness is less than 30 nm, then the conductivity can be reduced and the resistance increased, which results in a decrease in photoelectric conversion efficiency. If the film thickness is greater than 300 nm, then light transmittance may be lowered. Also, the sheet resistance of the front electrode (22) is typically 10Ω/sq or less. Further, the front electrode (22) may be a single layer or laminated layers formed of materials each having a different work function.

The back electrode (23) can be used as a cathode or anode depending on the set-up of the circuit. This electrode (23) can be made of a transparent or translucent conductive material. Alternatively, it (23) can be made of opaque or reflective material. This electrode (23) can be stacked on the photoactive layer (10). The material used for the back electrode (23) can be conductive. Non-limiting examples of such materials include metals, metal oxides, and conductive polymers (e.g., polyaniline, polythiophene, etc.) such as those discussed above in the context of the front electrode (22). When the front electrode (22) is formed using a material having high work function, then the back electrode (23) can be made of material having a low work function. Non-limiting examples of materials having a low work function include Li, In, Al, Ca, Mg, Sm, Tb, Yb, Zr, Na, K, Rb, Cs, Ba, and the alloys thereof. The back electrode (13) can be a single layer or laminated layers formed of materials each having a different work function. Further, it may be an alloy of one or more of the materials having a low work function and at least one selected from the group consisting of gold, silver, platinum, copper, manganese, titanium, cobalt, nickel, tungsten, and tin. Examples of the alloy include a lithium-aluminum alloy, a lithium-magnesium alloy, a lithium-indium alloy, a magnesium-silver alloy, a magnesium-indium alloy, a magnesium-aluminum alloy, an indium-silver alloy, and a calcium-aluminum alloy. The film thickness of the back electrode (23) can be from 1 to 1000 nm or from 10 to 500 nm. If the film thickness is too small, then the resistance can be excessively large and the generated charge may not be sufficiently transmitted to the external circuit.

In some embodiments, the front (22) and back (23) electrodes can be further coated with hole transport or electron transport layers (not shown in FIG. 1) to increase the efficiency and prevent short circuits of the organic photovoltaic cell (1). The hole transport layer and the electron transport layer can be interposed between the electrode and the photoactive layer (10). Non-limiting examples of the materials that can be used for the hole transport layer include polythiophene-based polymers such as PEDOT/PSS (poly(3,4-ethylenedioxythiophene)-poly(styrene sulfonate)) and organic conductive polymers such as polyaniline and polypyrrole. The film thickness of the hole transport layer can be from 20 to 100 nm. If the film thickness is too thin, short circuit of the electrode can occur more readily. If the film thickness is too thick, the film resistance is large and the generated electric current could be limited and optical conversion efficiency can be reduced. As for the electron transport layer, it can function by blocking holes and transporting electrons more efficiently. Non-limiting examples of the type of material that the electron transport layer can be made of include metal oxides (e.g., amorphous titanium oxide). When titanium oxide is used, the film thickness can range from 5 to 20 nm. If the film thickness is too thin, the hole blocking effect can be reduced and thus the generated excitons are deactivated before the excitons dissociate into electrons and holes. By comparison, when the film thickness is too thick, the film resistance is large, the generated electric current is limited, resulting in reduction of optical conversion efficiency.

### EXAMPLES

The present invention will be described in greater detail by way of specific examples. The following examples are offered for illustrative purposes only, and are not intended to limit the invention in any manner. Those of skill in the art will readily recognize a variety of noncritical parameters which can be changed or modified to yield essentially the same results.

### Example 1

(Materials, Methods, and Procedures)

Materials. All ACS grade solvents were purchased from Caledon Labs (Caledon, Ontario, Canada) and used without further purification unless otherwise stated. Tri-n-hexylchlorosilane was purchased from Gelest (Morrisville, Pa., USA) and used as received. Deuterated chloroform (CDCl₃) with 0.05 v/v % tetramethylsilane (TMS) was purchased from Cambridge Isotope Laboratories, Inc. (St. Leonard, Quebec, Canada) and used as received. Thin layer chromatography (TLC) was performed on aluminum plates coated with silica (pore size of 60 Å) and fluorescent indicator, obtained from Whatman Ltd, and visualized under UV (254 nm) light. Column chromatography was performed using Silica Gel P60 (mesh size 40-63 μm) obtained from SiliCycle Inc. (Quebec City, Quebec, Canada). Hydroxy-boron subphthalocyanine (HO—BsubPc) (Fulford, et al., 2012), dichloro silicon phthalocyanine ((Cl)₂—SiPc) (Lowery, et al., Inorg Chem. 1965, 4:128-128) and dichloro germanium phthalocyanine ((Cl)₂—GePc) (Joyner & Kenney, Journal of the American Chemical Society, 1960, 82:5790-5791), 3-pentadecylphenoxy boron subphthalocyanine (PDP—BsubPc) (Brisson, et al., Industrial and Engineering Chemistry Research 2011, 50:10910-10917.), 3-methylphenoxy boron subphthalocyanine (3MP—BsubPc) (Paton, et al., Industrial and Engineering Chemistry Research, 2012, 51:6290-6296) and pentafluorophenoxy boron subphthalocyanine (F₅—BsubPc) (Morse, et al., ACS Applied Materials & Interfaces. 2010, 2:1934-1944) were all prepared according to the literature.

Methods. All reactions were performed under an atmosphere of argon gas using oven-dried glasswares. Nuclear magnetic resonance (NMR) spectra were recorded on a Bruker Avance III spectrometer at 23° C. in CDCl₃, operating at 400 MHz for ¹H NMR and 100 MHz for ¹³C NMR. Chemical shifts (δ) are reported in parts per million (ppm) referenced to tetramethylsilane (0 ppm) for ¹H NMR and CDCl₃ (77.16 ppm) for ¹³C NMR. Coupling constants (J) are reported in hertz (Hz). Spin multiplicities are designated by the following abbreviations: s (singlet), d (doublet), t (triplet), q (quartet), m (multiplet) and br (broad). Accurate mass determinations (HRMS) were carried out on a GCT Premier TOF mass spectrometer (Waters Corporation, Milford, Mass., USA). Low resolution mass spectroscopy (LRMS) were acquired on a AccuTOF model JMS-T1000LC mass spectrometer (JEOL USA Inc., Peabody, Mass., USA) equipped with a Direct Analysis in Real Time (DART) ion source or on a GC Premier TOF mass spectrometer (Waters Corporation, Milford, Mass., USA) with EI/CI sources. Ultraviolet-visible (UV-vis) absorption spectra were acquired on a PerkinElmer Lambda 1050 UV/VIS/NIR spectrometer using a PerkinElmer quartz cuvette with a 10 mm path length. Photoluminescence (PL) spectra were recorded on a PerkinElmer LS55 fluorescence spectrometer using a PerkinElmer quartz cuvette with a 10 mm path length. High pressure liquid chromatography (HPLC) analysis was carried out on a Waters 2695 separation module with a Waters 2998 photodiode array and a Waters Styragel® HR 2 THF 4.6×300 mm column. The mobile phase used was HPLC grade acetonitrile (80% by volume) and N,N-dimethylformamide (20% by volume). Cyclic voltammetry was carried out using a Bioanalytical Systems C3 electrochemical workstation. The working electrode was a 2 mm glassy carbon disk, the counter electrode was a platinum wire, and the reference electrode was Ag/AgCl₂ saturated salt solution. Spec-grade dichloromethane was purged with nitrogen gas at room temperature prior to its use. Three cycles from +1.7 to −1.7 V at a scan rate of 100 mV/s were measured for each sample. Tetrabutylammonium perchlorate (1 M) was used as the supporting electrolyte and Decamethylferrocene was used as an internal reference.

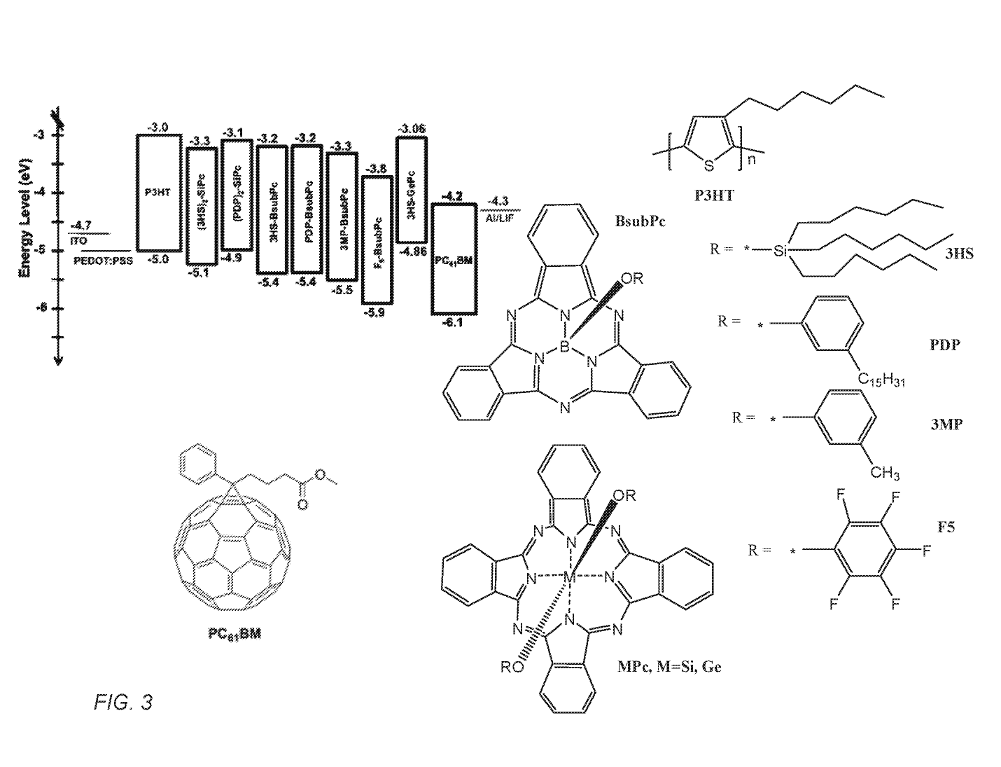

Tri-n-hexylsiloxy-boron subphthalocyanine (3HS—BsubPc) (FIG. 3). To an oven-dried three-neck round bottom flask was added HO—BsubPc (0.50 g, 1.21 mmol, 1 equiv), 1,2-dichlorobenzene (20 mL), and tri-n-hexylchlorosilane (0.90 mL, 2.46 mmol, 2 equiv) under argon. The reaction mixture was heated to 130° C. and the reaction was monitored by HPLC (acetonitrile:N,N-dimethylformamide—80:20 v/v) for the consumption of HO—BsubPc. Once the reaction had stopped progressing (˜5 hours), the reaction mixture was cooled to room temperature before it was concentrated under reduced pressure to a dark pink liquid. Note that further addition of tri-n-hexylchlorosilane to the reaction mixture did not consume any unreacted HO—BsubPc. The crude product was purified via silica gel column chromotography using 100% hexane to first elute unreacted tri-n-hexylchlorosilane and other silane derivatives, followed by a gradient to 20% THF solution in hexane (v/v) to elute the target compound as a bright pink solid (yield=49%) following rotary evaporation. ¹H NMR (400 MHz, CDCl₃) δ 8.87-8.81 (m, 6H), 7.92-7.85 (m, 6H), 1.14-1.04 (m, 6H), 0.96-0.89 (m, 6H), 0.89-0.81 (m, 6H), 0.78 (t, J=7.3 Hz, 9H), 0.51-0.42 (m, 6H), −0.38-−0.45 (m, 6H); ¹³C NMR (100 MHz, CDCl₃) δ 151.0, 131.2, 129.6, 122.2, 33.2, 31.6, 22.9, 22.7, 14.5, 14.3; HRMS (EI) [M] calcd for 694.3987, found 694.3990.

Bis(hydroxy)-silicon phthalocyanine ((HO)₂—SiPc) (FIG. 3). To an oven-dried three-neck round bottom flask was added Cl₂—SiPc (2.5 g, 4.09 mmol, 1 equiv), 1,2-dichlorobenzene (25 mL), and cesium hydroxide (1.50 g, 10.0 mmol, 2.5 equiv) under argon. The reaction mixture was heated to 120° C. for 4 hour. The crude product was precipitated into methanol and filtered to give a dark blue powder (crude yield=54%), which was used without further purification. LRMS (EI) calc'd for 574.62, found 574.1.

Bis(hydroxy)-germanium phthalocyanine ((HO)₂—GePc) (FIG. 3). (HO)₂—GePc was synthesized using the same method as (HO)₂—SiPc. The crude product was precipitated into methanol and filtered to give a dark blue solid (crude yield=78%), which was used without further purification. Mass spectrometry data could not be obtained as fragmentation of the title compound occurs.

Bis(tri-n-hexylsiloxy)-silicon phthalocyanine ((3HS)₂—SiPc) (FIG. 3). (3HS)₂—SiPc was synthesized from (HO)₂—SiPc by adapting the patent literature (Gessner, et al., U.S. Patent Publication No. 2010/0113767). To an oven-dried three-neck round bottom flask was added (HO)₂—SiPc (1.00 g, 1.61 mmol, 1 equiv), pyridine (100 mL), tri-n-hexylchlorosilane (4.85 g, 17.1 mmol, 5 equiv per reactive site) under argon. The reaction mixture was heated to 130° C. for 5 h before it was cooled to room temperature. The crude product was precipitated into water, filtered, washed with water (3×), and dried in a vacuum oven to give a dark blue solid (yield=79% before column chromatography, purity>90% as determined by ¹H NMR). The crude product was purified via silica gel column chromatography using 100% hexane to first elute unreacted tri-n-hexylchlorosilane and other silane derivatives, followed by a gradient to 50% THF solution in hexane (v/v) to elute the target compound as a dark blue solid (yield=47%) following rotary evaporation. Single crystals of (3HS)₂—SiPc were grown by slow cooling from hot pyridine solution. ¹H NMR (400 MHz, CDCl₃) δ 9.66-9.60 (m, 8H), 8.33-8.28 (m, 8H), 0.87-0.79 (m, 12H), 0.74-0.67 (t, J=7.2 Hz, 18H), 0.62-0.55 (m, 12H), 0.40-0.32 (m, 12H), 0.06-−0.03 (m, 12H), −1.21-−1.35 (m, 12H); ¹³C NMR (100 MHz, CDCl₃) δ 148.9, 136.4, 130.6, 123.6, 33.6, 33.4, 32.8, 31.8, 31.7, 31.1, 23.4, 23.2, 22.80, 22.75, 22.6, 21.5, 16.0, 15.2, 14.31, 14.29, 14.27, 12.9; LRMS (EI) m/z [M+H]⁺calcd for 1139.78, found 1139.7.

Bis(tri-n-hexylsiloxy)-germanium phthalocyanine ((3HS)₂—GePc) (FIG. 3). (3HS)₂—GePc was synthesized from (OH)₂—GePc in an identical fashion to that of (3HS)₂—SiPc. The title compound was obtained as a dark blue solid (yield=49%). Single crystals of (3HS)₂—GePc were grown by slow cooling from DCM/hexanes. ¹H NMR (400 MHz, CDCl₃) δ 9.66-9.61 (m, 8H), 8.34-8.29 (m, 8H), 0.86-0.78 (m, 12H), 0.73-0.68 (m, 18H), 0.62-0.55 (m, 12H), 0.41-0.32 (m, 12H), 0.06-−0.02 (m, 12H), −1.07-−1.17 (m, 12H); ¹³C NMR (100 MHz, CDCl₃) δ 149.6, 135.9, 131.5, 124.1, 33.4, 32.7, 31.7, 31.1, 29.92, 29.87, 23.2, 22.8, 22.5, 21.7, 15.2, 14.3, 14.3, 13.4. Mass spectrometry data could not be obtained as fragmentation of the title compound occurs.

Bis(3-Pentadecylphenoxy)-silicon phthalocyanine ((PDP)₂—SiPc) (FIG. 3). In a procedure adapted from Brisson et al., 2011, Cl₂—SiPc (0.5 g, 0.82 mmol, 1 equiv) and 3-pentadecylphenol (0.60 g, 1.97 mmol, 2.4 equiv) were added to chlorobenzene (30 mL) under argon, and heated to 120° C. for 22 h. Upon cooling to room temperature, the reaction mixture was concentrated to dryness via rotary evaporation. Some of the 3-pentadecylphenol was removed via distillation at 200° C. using a rotary evaporator equipped with a high vacuum pump. The resulting dark blue solid was eluted on a silica gel column using DCM as the eluent. The first eluted blue band was collected, concentrated, and dried in a vacuum oven to give a dark blue solid (yield=38%). Single crystals of (PDP)₂—SiPc were grown by slow evaporation from dichloromethane solution. ¹H NMR (400 MHz, CDCl₃) 9.68-9.61 (m, 8H), 8.38-8.30 (m, 8H), 5.55-5.51 (m, 2H), 5.51-5.46 (t, J=7.5 Hz, 2H), 2.34-2.29 (m, 2H), 2.26-2.23 (m, 2H), 1.39-1.26 (m, 40H), 1.25-1.16 (m, 4H), 1.14-1.04 (m, 4H), 0.96-0.90 (m, 6H), 0.85-0.75 (m, 4H), 0.61-0.50 (m, 4H); ¹³C NMR (100 MHz, CDCl₃) δ 149.8, 149.3, 142.1, 135.9, 131.1, 126.6, 123.9, 119.5, 117.5, 114.8, 34.8, 32.1, 30.5, 30.0, 29.94, 29.88, 29.8, 29.6, 29.5, 29.3, 22.9, 14.3; HRMS (DART) m/z [M+H]⁺ calcd for 1147.61, found 1147.6.

P3HT:PC₆₁BM OPV Device. P3HT:PC₆₁BM:Dye: containing devices were made by dissolving the P3HT, PC₆₁BM and the dye in 1,2-dichlorobenzene (40 mg/mL solutions) and were allowed to stirred at 50° C. for 2-3 h to ensure complete dissolution of the solids. Indium tin oxide (ITO) coated glass substrates (Colorado Concept Coatings LLC) were rubbed with aqueous detergent followed by ultrasonication in aqueous detergent, deionized water, acetone, and methanol for 5 minutes each, followed by an oxygen-plasma treatment for 15 minutes. A thin layer of poly(3,4-ethylenedioxythiophene):poly(styrene sulfonic acid) (PEDOT:PSS) was then spin-coated onto the ITO glass at 3000 rpm for 30 seconds, and dried in air at 140° C. on a hotplate for 15 min. Prior to spin coating the active layer, the P3HT, the PC₆₁BM and the dye solutions were stirred together for 15 min. The ternary mixtures were then spin-coated onto the PEDOT:PSS coated substrates at 600 rpm under nitrogen atmosphere and allowed to dry at room temperature for 20 h. No annealing was performed on these devices. The substrates were then coated with lithium fluoride (LiF, 0.8 nm) and aluminum (Al, 100 nm) by thermal evaporation using an Angstrom Engineering (Kitchener, ON) Covap II metal evaporation system at 0.7-2.0×10⁻⁶ torr. The device area is 0.07 cm² as defined by a shadow mask and the IV curves were obtained using a Keithley 2400 source meter under simulated AM 1.5 G conditions with a power intensity of 100 mWcm⁻². The mismatch of similar spectrum was calibrated using a Si diode with a KG-5 filter. EQE measurements were recorded using a 300 W Xenon lamp with an Oriel Cornerstone 260 ¼ m monochromator and compared with a Si reference device that is traceable to the National Institute of Standards and Technology.

### Example 2

(Results)

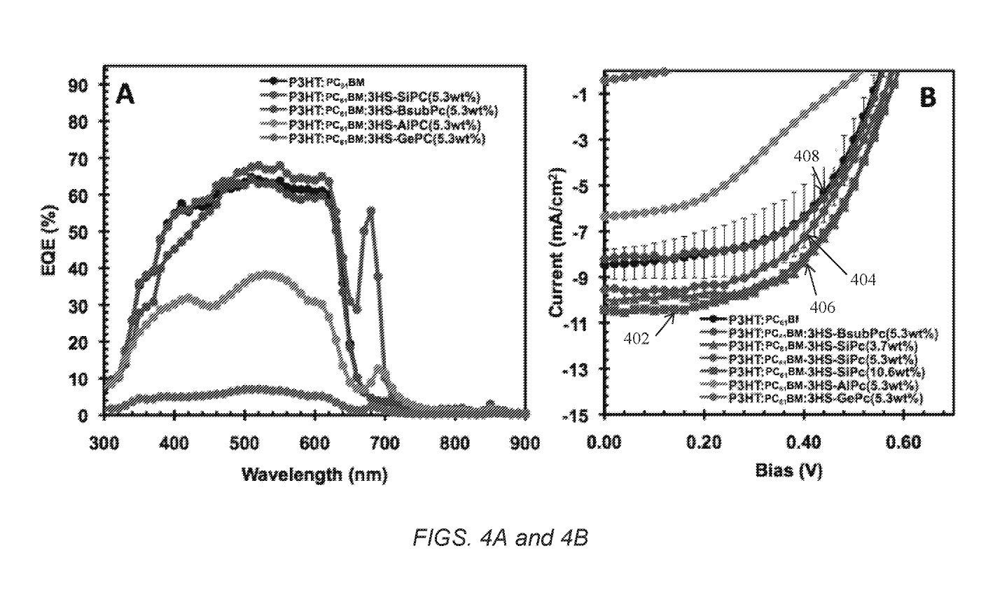

Baseline P3HT:PC₆₁BM BHJ Devices. A series of baseline BHJ devices using the structure ITO/PEDOT:PSS/Active Layer/LiF/Al, where the active layer was a 1.0:0.8 mixture of P3HT:PC₆₁BM were repeatedly fabricated throughout the entire study and constantly analyzed and compared. The resulting BHJ OPV devices were determined to have J_{SC}=8.15±0.78 mA·cm⁻², V_{OC}=0.62±0.02 V, FF=0.55±0.03 and η_{eff}=2.75±0.21 (averaged over at least 40 devices). A representative IV curve with error bars and EQE plot for an average P3HT:PC₆₁BM device are shown in FIGS. 4A and 4B. FIG. 4A is a characteristic external quantum efficiency (EQE) curve of EQE % versus wavelength. FIG. 4B are IV curves (current in mA/cm² versus bias in Volts) for the P3HT:PC₆₁BM (1.0:0.8, mass ratio) and P3HT:PC₆₁BM:X (1.0:0.8:Y), where X=bis(tri-n-hexylsilyl oxide) silicon phthalocyanine ((3HS)₂—SiPc, 1), tri-n-hexylsilyl oxide boron subphtahlocyanine (3HS—BsubPc) and bis(tri-n-hexylsilyl oxide) germanium phthalocyanine ((3HS)₂—GePc) and where Y=0.2 (10.6 wt %, open squares, data line 402), 0.1 (5.3 wt %, filled circles, data line 404) or 0.07 (3.7 wt %, open triangles, data line 406). Standard P3HT:PC₆₁BM BHJ solar device data (no tertiary additive, data line 408) is shown with error bars to illustrate the space occupied by standard devices.

P3HT:PC₆₁BM cascade OPVs using (3HS)₂—SiPc. (3HS)₂—SiPc was then evaluated as an additive in P3HT:PC₆₁BM BHJ OPV devices with identical device structure to the baseline P3HT:PC₆₁BM OPVs device. The characteristic IV curves and external quantum efficiency (EQE) plots are illustrated in FIGS. 4A and 4B and the statistics of all the replicates can be found in Table 1. A peak at ≈700 nm due to the SiPc chromophore in the EQE, an increase in J_{SC} of 7-25% and an increase in η_{eff} of 15-20% were all observed (FIG. 4, Table 1). Adding as much as 10 wt % (3HS)₂—SiPc a decrease in FF was observed, which resulted in a slight decrease in η_{eff} (FIG. 4). AFM and contact angle studies using roughly 5 wt % (3HS)₂—SiPc determined that 40% of the SiPc molecules are located at the interface.

TABLE 1
(P3HT:PC₆₁BM:X (where X is tertiary additive) BHJ OPV Device Characterization)

| P3HT:PC₆₁BM:X^{a)} | | | J_{SC} | | | η_{Power} |
|---|---|---|---|---|---|---|
| (mass ratio) | Wt %^{b)} | X | [mA cm⁻²] | V_{OC} [V] | FF [%] | [%] |
| 1:0.8:0 | — | — | 8.48 ± 0.42 | 0.57 ± 0.01 | 0.56 ± 0.03 | 2.74 ± 0.22 |
| 1:0.8:0.2 | 10.6 | (3HS)₂—SiPc | 10.58 ± 0.27 | 0.59 ± 0.02 | 0.51 ± 0.01 | 3.17 ± 0.08 |
| 1:0.8:0.1 | 5.3 | (3HS)₂—SiPc | 9.10 ± 0.82 | 0.56 ± 0.02 | 0.52 ± 0.02 | 2.68 ± 0.38 |
| 1:0.8:0.07 | 3.7 | (3HS)₂—SiPc | 9.84 ± 0.15 | 0.57 ± 0.005 | 0.59 ± 0.01 | 3.29 ± 0.09 |
| 1:0.8:0.1 | 5.3 | (3HS)₂—GePc | 0.35 ± 0.03 | 0.12 ± 0.01 | 0.24 ± 0.01 | 0.012 ± 0.002 |
| 1:0.8:0.07 | 3.7 | (3HS)₂—GePc | 0.62 ± 0.01 | 0.16 ± 0.01 | 0.24 ± 0.01 | 0.023 ± 0.002 |
| 1:0.8:0.2 | 10.6 | 3HS-BsubPc | 8.75 ± 0.28 | 0.55 ± 0.005 | 0.44 ± 0.04 | 2.10 ± 0.18 |
| 1:0.8:0.1 | 5.3 | 3HS-BsubPc | 8.69 ± 0.43 | 0.56 ± 0.01 | 0.57 ± 0.01 | 2.76 ± 0.15 |
| 1:0.8:0.07 | 3.7 | 3HS-BsubPc | 9.20 ± 0.32 | 0.55 ± 0.005 | 0.58 ± 0.01 | 2.92 ± 0.07 |
| 1:0.8:0.2 | 10.6 | PDP-BsubPc | 7.69 ± 0.33 | 0.57 ± 0.005 | 0.52 ± 0.18 | 2.27 ± 0.18 |
| 1:0.8:0.1 | 5.3 | PDP-BsubPc | 7.77 ± 0.23 | 0.57 ± 0.005 | 0.51 ± 0.04 | 2.26 ± 0.22 |
| 1:0.8:0.07 | 3.7 | PDP-BsubPc | 7.90 ± 0.27 | 0.55 ± 0.005 | 0.61 ± 0.01 | 2.63 ± 0.11 |
| 1:0.8:0.2 | 10.6 | 3MP-BsubPc | 6.99 ± 0.51 | 0.51 ± 0.03 | 0.37 ± 0.01 | 1.30 ± 0.16 |
| 1:0.8:0.1 | 5.3 | 3MP-BsubPc | 7.03 ± 0.62 | 0.57 ± 0.005 | 0.47 ± 0.01 | 1.90 ± 0.15 |
| 1:0.8:0.1 | 5.3 | F₅-BsubPc | 6.68 ± 0.78 | 0.50 ± 0.01 | 0.33 ± 0.02 | 1.08 ± 0.06 |
| 1:0.8:0.1:0.1^{c)} | 5.3/5.3 | F₅/3MP-BsubPc | 6.93 ± 0.31 | 0.48 ± 0.02 | 0.29 ± 0.005 | 0.96 ± 0.09 |
| 1:0.8:0.05:0.05^{c)} | 2.7/2.7 | F₅/3MP-BsubPc | 8.27 ± 0.40 | 0.56 ± 0.01 | 0.37 ± 0.01 | 1.68 ± 0.14 |
| 1:0.8:0.2 | 10.6 | (PDP)₂—SiPc | 8.94 ± 0.09 | 0.58 ± 0.01 | 0.46 ± 0.01 | 2.34 ± 0.03 |
| 1:0.8:0.1 | 5.3 | (PDP)₂—SiPc | 7.94 ± 0.20 | 0.58 ± 0.01 | 0.53 ± 0.01 | 2.44 ± 0.08 |
| 1:0.8:0.07 | 3.7 | (PDP)₂—SiPc | 9.49 ± 0.20 | 0.59 ± 0.01 | 0.54 ± 0.01 | 3.02 ± 0.08 |

^{a)}Mass ratio used to fabricate the active layer of the bulk heterojunction organic photovoltaic (BHJ-OPV) devices, where P3HT represents Poly(3-hexylthiophene), PC₆₁BM represents phenyl-C₆₁-butyric acid methyl ester, (3HS)₂—SiPc represents bis(tri-n-hexylsilyl oxide) silicon phthalocyanine, 3HS-BsubPc represents tri-n-hexylsilyl oxide boron subphtahlocyanine, (3HS)₂—GePc represents bis(tri-n-hexylsilyl oxide) germanium phthalocyanine and (PDP)₂—SiPc represents Bis(3-Pentadecylphenoxy)-silicon phthalocyanine.
^{b)}wt % is the weight percent of the additive relative to the P3HT:PC₆₁BM.
^{c)}quaternary BHJ OPV devices: P3HT:PC₆₁BM: 3MP-BsubPc:F₅-BsubPc.

In all cases experiments the values were averaged with a minimum of 4-5 devices in the case of Exp. A, B and C the values were averaged over a minimum of 2-3 devices with 4-5 pixels on each device fabricated over the span of 8-12 weeks in the same apparatus. The values were obtained under AM1.5G irradiation at 100 mWcm⁻².

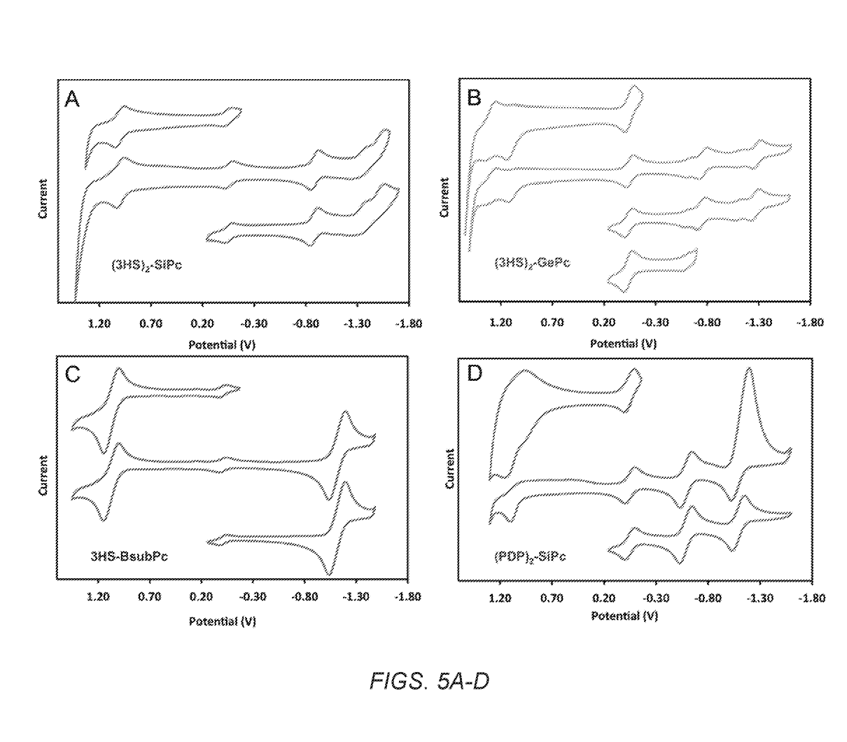

P3HT:PC₆₁BM cascade OPVs using phthalocyanine variants. bis(tri-n-hexylsilyl oxide) germanium phthalocyanine ((3HS)₂—GePc,) was introduced (3HS)₂—GePc into identical P3HT:PC₆₁BM BHJ OPV devices. The opposite effect was observed to what was found for (3HS)₂—SiPc. As little as 3.7 wt % (3HS)₂—GePc resulted in a significant decrease in EQE across the spectrum as well as a decrease in FF, J_{SC} and η_{eff} (FIGS. 4A and 4B, Table 1). UV-Vis absorbance spectroscopy and electrochemical analysis were performed on both (3HS)₂—SiPc and (3HS)₂—GePc. Their respective cyclic voltammograms are illustrated in FIGS. 5(A) and (B) and their calculated HOMO and LUMO energy levels along with the absorption maxima are summarized in FIG. 3 and Table 2. Double reversible oxidation and reduction peaks are observed for (3HS)₂—GePc, a finding not observed for (3HS)₂—SiPc, which is presumably due to the unique Si—O—Ge—O—Si sequence in (3HS)₂—GePc. (3HS)₂—GePc has significantly different HOMO and LUMO levels than (3HS)₂—SiPc (FIG. 3). The difference in the HOMO and LUMO levels result in a straddling configuration with P3HT and therefore (3HS)₂—GePc can be assumed to act as a charge trap in a P3HT:PC₆₁BM OPV rather than facilitating the cascade electron transfer effect; an assertion that is consistent with the observation of a significantly reduced EQE spectrum and overall OPV device performance when (3HS)₂—GePc is present. Cyclic voltammograms for (3HS)—BsubPc and (PDP)₂—SiPc are illustrated in FIGS. 5(C) and (D).

TABLE 2
(Electrochemical characterization of the tri-n-hexylsiloxy-boronsubphthalocyanine
(3HS—BsubPc))

| | E _{OX, 1/2} | E _{Red, 1/2} | E _{HOMO}¹ | E _{LUMO}² | λ _{MAX}³ | E _{Gap,Opt}⁴ |
|---|---|---|---|---|---|---|
| Sample | (V) | (V) | (eV) | (eV) | (nm) | (eV) |
| (3HS)₂—SiPc | −0.85 | 1.04 | −5.11 | −3.23/−3.29 | 663/669 | 1.82 |
| 3HS-BsubPc | −1.12 | 1.07 | −5.39 | −3.20/−3.32 | 571/561 | 2.07 |
| (3HS)₂—GePc | −0.59, −0.72, −1.10, −1.25 | 1.11, 1.34 | −4.86 | −3.16/−3.06 | 674/678 | 1.80 |
| (PDP)₂—SiPc | −0.65, −1.17 | 0.98 | −4.92 | −3.30/−3.11 | 681/765 | 1.78 |

¹EHOMO = (E OX, 1/2 ) − (4.27) eV (scaled to an internal standard of decamethylferrocene
²ELUMO, Electro/ELUMO, Opt where ELUMO, Electro = (E Red, 1/2 ) − (4.27) eV and ELUMO, Opt = EGap,Opt − EHOMO
³Maximum absorbance, λ_{MAX}, of respective compounds where λ_{MAX, solution}/λ_{MAX, film}
⁴E _{Gap,Opt} determined from the onset of the solution absorbance spectra.

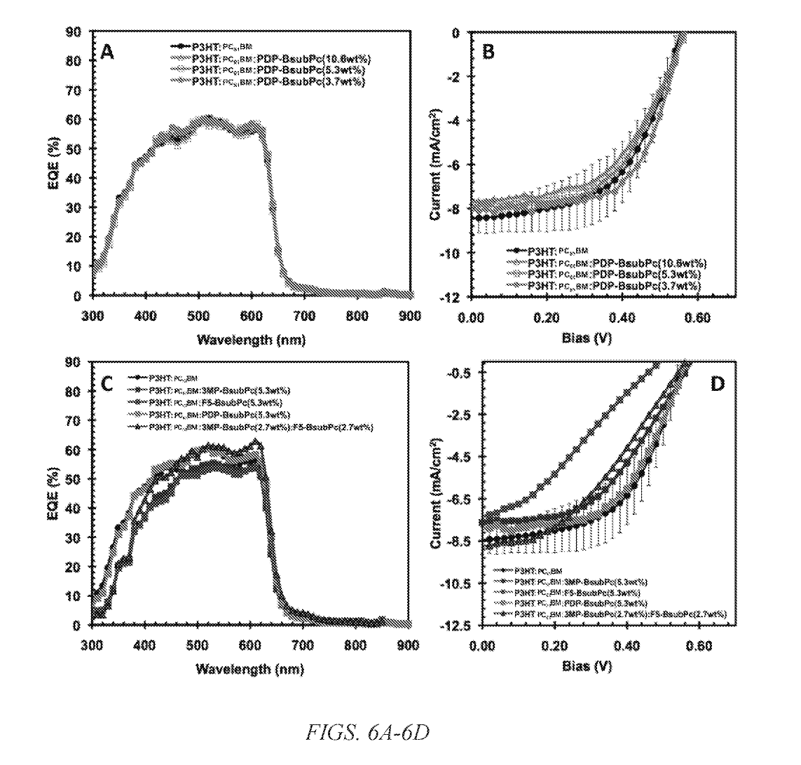

A boron subphthalocyanines (BsubPc) analogue to (3HS)₂—SiPc (i.e., tri-n-hexylsilyl oxide boron subphthalocyanine (3HS—BsubPc) was synthesized and tested with the above baseline P3HT:PC₆₁BM BHJ device. It was exceptionally soluble in common organic solvents. Optical and electrochemical characterization of 3HS—BsubPc were performed and the results are outlined and tabulated in FIG. 3, FIG. 6, and Table 2. Based on the measured CV behavior and the calculated HOMO and LUMO energy levels, similar to (3HS)₂—SiPc, 3HS—BsubPc should result in a cascade BHJ when mixed with P3HT and PC₆₁BM (FIG. 1). Unlike (3HS)₂—SiPc, the absorbance of the 3HS—BsubPc chromophore is at ≈545 nm and therefore any photo charge generation from 3HS—BsubPc at low loadings is indistinguishable from charge generated by the combination of P3HT and PC₆₁BM (FIG. 4A). Photogeneration from the BsubPc chromophore was observed at increased loadings or when removing PC₆₁BM from the mixture and making a device with just another BsubPc derivative and P3HT. The addition of 3HS—BsubPc at three different mass loadings did not result in a statistical difference in the measured J_{SC} or V_{OC} of the BHJ OPV device (FIG. 4B, Table 1). The lack of increase in J_{SC} with the addition of 3HS—BsubPc indicates that there is no significant cascade effect between the P3HT and PC₆₁BM via the intermediacy of 3HS—BsubPc despite favorable alignment of the frontier orbitals. Based on this it was concluded that a significant portion of 3HS—BsubPc molecules are solubilized in either the P3HT and PC₆₁BM layer rather than being present at the P3HT:PC₆₁BM interface thereby not facilitating the desired electron transfer events.

The following three additional BsubPc derivatives were also incorporated into the above baseline P3HT:PC₆₁BM BHJ device: 3-pentadecyl-phenoxy-BsubPc (Brisson, et al., 2011) (PDP—BsubPc, FIG. 3), 3-methyl-phenoxy-BsubPc (Paton, et al., 2012) (3MP—BsubPc, FIG. 3) and pentafluoro-phenoxy-BsubPc (Morse, et al., 2010; Helander, et al., ACS Applied Materials & Interfaces, 2010, 2:3147-3152, 2010) (F₅—BsubPc, FIG. 3). These three BsubPcs have similar energy levels to that of 3HS—BsubPc and therefore meet the energetic criteria to facilitate a cascade electron transfer between P3HT and PC₆₁BM (FIG. 4). Each has either similar or differing physical properties than 3HS—BsubPc. For instance, PDP—BsubPc is also highly soluble and the pentadecyl phenoxy fragment has a similar carbon number to the trishexyl silyl fragment. 3MP—BsubPc is an anomalously soluble and crystalline version of BsubPc with a low carbon number for its phenoxy fragment (Paton, et al., 2012). Finally, F₅—BsubPc is also both relatively soluble and crystalline but has HOMO and LUMO energy levels distinctly different from other BsubPcs (Helander, et al., 2010) (FIG. 3). Table 1 provides the data for these additives in the ternary BHJ OPV device.

Beginning with PDP—BsubPc, the characteristic external quantum efficiency (EQE) and IV curves and plots for P3HT:PC₆₁BM:PDP—BsubPc ternary BHJ OPV device are illustrated in FIG. 6A and FIG. 4B, respectively. When adding 3.7 wt % PDP—BsubPc a statistically insignificant increase in J_{SC}, no change in V_{OC} but a statistically significant improvement in FF (61% from 56%) was observed compared to the baseline P3HT:PC₆₁BM BHJ OPV devices. Increasing the amount of PDP—BsubPc resulted in a statistically significant decrease in device characteristics (FIG. 6B, Table 1). Whereas, the addition of 3MP—BsubPc or F₅—BsubPc resulted in negligible increases in J_{SC} and a significant decreases in V_{OC} and FF (FIG. 6B, Table 1).

FIGS. 6C and 6D each illustrate the comparison between the addition of 5.3 wt % 3MP—BsubPc, F₅—BsubPc and PDP—BsubPc to the P3HT:PC₆₁BM BHJ OPV device and the use of a mixture of 2.7 wt % 3MP—BsubPc and 2.7 wt % F₅—BsubPc in the same P3HT:PC₆₁BM BHJ OPV device. The combination of 3MP—BsubPc and F₅—BsubPc was tested with the idea that the energetic differences between P3HT, PC₆₁BM, 3MP—BsubPc and F₅—BsubPc would create a favorable cascade of electron transfer events with lower energetic barrier (FIG. 3) and an increase in extracted current. Using the combination of 2.7 wt % 3MP—BsubPc and 2.7 wt % F₅—BsubPc the P3HT:PC₆₁BM OPV did exhibit a statistically significant increase in J_{SC} compare to the use 5.3 wt % 3MP—BsubPc or 5.3 wt % F₅—BsubPc alone (Table 1, FIG. 6B) but still a reduction in J_{SC} compared to the P3HT:PC₆₁BM baseline device. The measured V_{OC} was unchanged and a more pronounced peak at 610 nm in the EQE spectra was observed when the mixture was used compared to the use of 3MP—BsubPc or F₅—BsubPc alone (FIG. 6B). However, the FF was significantly reduced to 37% for the mixture, which is in between the FF of 47% and 33% obtained when using simply 3MP—BsubPc or F₅—BsubPc, respectively (FIGS. 6C and 6D).

The sum of these results suggest that while the BsubPc chromophore has the correct frontier orbital energies to produce a cascade electron transfer between P3HT and PC₆₁BM phases, none of these compounds are as functional as 3H5—SiPc. It was concluded then that there is more to consider than this and it is not as simple as having a chromophore with either high or low solubility (take PDP—BsubPc vs F₅—BsubPc for example) and appropriate frontier orbital energy levels.

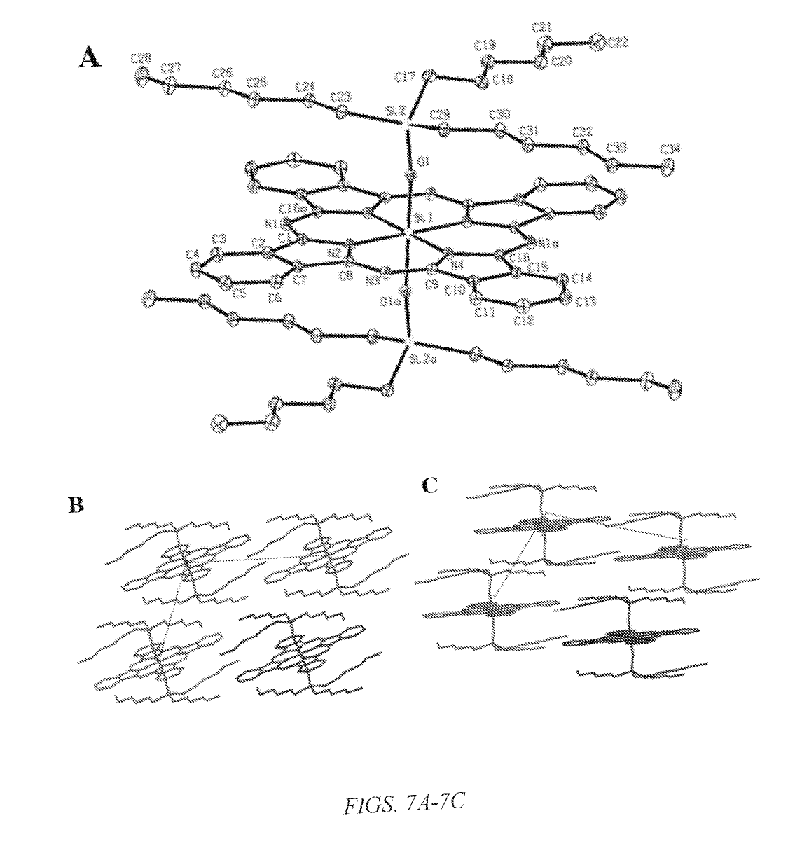

During the work with (3HS)₂—SiPc, it was observed that it has a unique combination of high solubility and a strong tendency to crystallize. Large single crystals of (3HS)₂—SiPc were unintentionally grown by leaving the crude (3HS)₂—SiPc in a hot pyridine solution and letting it cool to room temperature overnight. The single crystals were analyzed using X-ray diffraction at a low temperature (CCDC deposition number 988974) and the molecular structure and solid state arrangement of (3HS)₂—SiPc was determined with very high accuracy. The resulting thermal ellipsoid plot is illustrated in FIG. 7A, while FIGS. 7B and 7C represent the crystal structure arrangement of multiple (PDP)₂—SiPc molecules. In spite of the high number of degrees of freedom that would normally be assumed to be associated with a trihexylsilyl group, it was observed that the crystals of (3HS)₂—SiPc have no disorder in the hexyl chains. Furthermore, the positions of the carbon atoms of the trihexylsilyl groups are well fixed (as indicated by the tight thermal ellipsoids) indicating again a lack of disorder within the crystal. Regarding the solid state arrangement, (3HS)₂—SiPc arranges into a well ordered three dimensional matrix where all the SiPc chromophores are pointing in the same orientation and are separated by inter-stacking trihexylsilyl groups (FIGS. 5B and C).

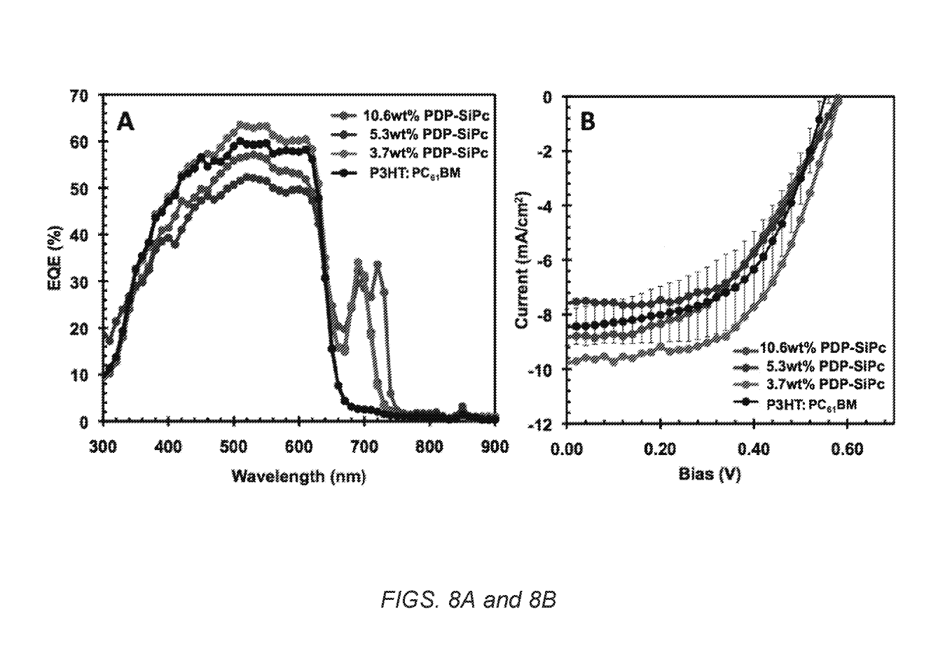

In order to determine if the trihexylsilyl groups are essential to the functionality of (3HS)₂—SiPc in a BHJ OPV device and its tendency to crystallize, an alternative SiPc derivative was synthesized: bis(3-pentadecylphenoxy)-silicon phthalocyanine ((PDP)₂—SiPc). (PDP)₂—SiPc was chosen as target because it is (or was expected to be) a highly soluble SiPc derivative (Brisson, et al., 2011). In addition, the 3-pentadecylphenoxy molecular fragment has a similar number of carbon atoms as the trihexylsilyl oxide group (21 vs. 18 carbon atoms). Electrochemical and spectroscopic characterization was performed on (PDP)₂—SiPc and the results are tabulated in Table 2. The respective HOMO and LUMO energy levels (calculated) are similar to those of (3HS)₂—SiPc and should, therefore, also facilitate a cascade electron transfer between the P3HT and PC₆₁BM. (PDP)₂—SiPc was therefore introduced into a series of P3HT:PC₆₁BM BHJ OPV devices using loadings of 3.7 wt %, 5 wt % and 10 wt %. The respective EQE spectra and IV curves for the BHJ OPV devices as well as the corresponding characteristics are illustrated in FIGS. 8A and 8B, and tabulated in Table 1. At low (PDP)₂—SiPc loadings (3.7 wt %) a noticeable increase in J_{SC} and consequently the η_{eff} was observed compared to the baseline P3HT:PC₆₁BM OPV (FIGS. 8A and 8B, Table 1). Once the loading was increased to 10 wt % a moderate increase in J_{SC} was observed, however, the significant drop in FF resulted in a drop in η_{eff}. At low loading this behavior is similar to (3HS)₂—SiPc but the similarity deviates at higher loadings.

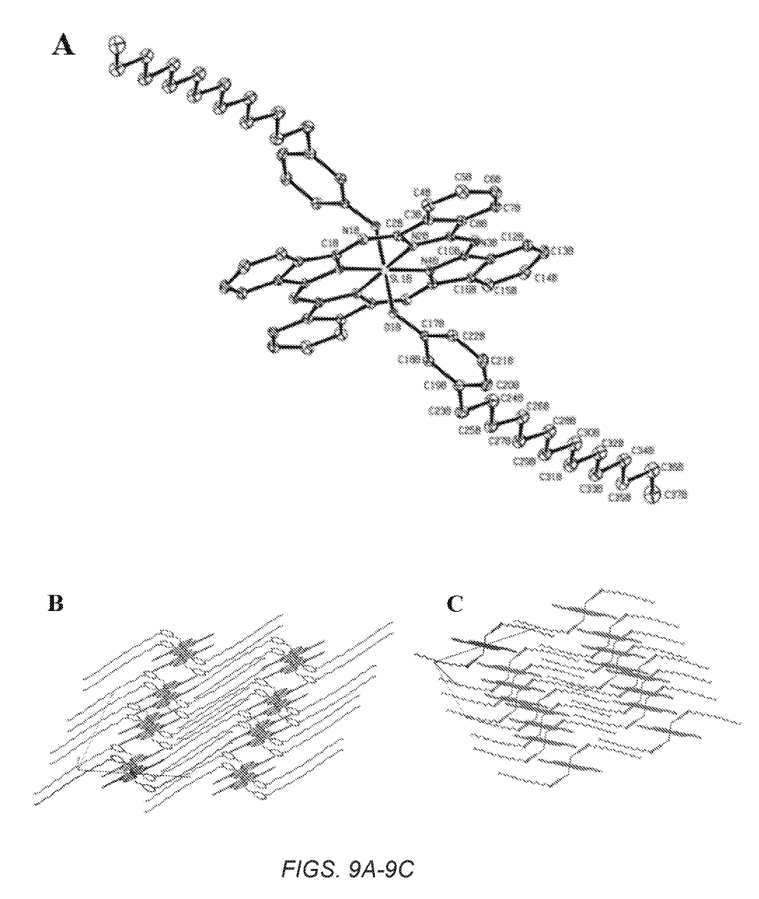

(PDP)₂—SiPc was also found to have a strong tendency to crystallize. This despite the expect large degrees of freedom of the 3-pentadecylphenoxy molecular fragments and the high overall solubility of (PDP)₂—SiPc. For instance, single crystals of (PDP)₂—SiPc could be obtained by either precipitation of a dichloromethane solution into acetonitrile or by simple slow evaporation of a dichloromethane solution. The single crystals of (PDP)₂—SiPc that were grown by slow evaporation of a dichloromethane solution were diffracted using x-ray crystallography (CCDC deposition number 988976). The resulting 50% ellipsoid probability plot is illustrated in FIG. 9A. The solid state arrangement of (PDP)₂—SiPc is quite different from that of (3HS)₂—SiPc (FIGS. 9B and 9C). For example, the SiPc chromophores are closely packed and separated in between the interdigitating pentadecyl fragments (FIGS. 9B and 9C).

When comparing the addition of (3HS)₂—SiPc versus the addition of (PDP)₂-SiPc under similar loadings to a ternary P3HT:PC₆₁BM BHJ OPV device it appears that (3HS)₂—SiPc is a more effective additive (Table 1, FIG. 7). For example, compared to the baseline P3HT: PC₆₁BM BHJ OPV device the addition of 3.7wt % of(3HS)₂—SiPc resulted in an increase in J_{SC} and η_{eff} of 16% and 20%, respectively, while the addition of 3.7 wt % of (PDP)₂—SiPc only resulted in an increase in J_{SC} and η_{eff} of 12% and 10%, respectively. These results indicate that a more significant cascade effect is taking place between P3HT and PC₆₁BM when (3HS)₂—SiPc is present. It is possible that (PDP)₂—SiPc has a higher solubility or affinity for the P3HT phase due hydrocarbon/hydrocarbon interaction between the n-hexyl chains of P3HT and the pentadecyl chains of (PDP)₂—SiPc resulting in a decrease in (PDP)₂-SiPc at the P3HT:PC₆₁BM interface. Such interactions might not be possible with (3HS)₂—SiPc due to the differences in geometry/location of the n-hexyl fragments. Another important observation is that a 3.7 wt % or 5.3 wt % loading of (PDP)₂—SiPc results in a EQE, at 700 nm, ≈30%, whereas a loading of 5.3 wt % of (3ES)₂—SiPc the resulting EQE, at 700 nm, ≈55% (FIGS. 4 and 8). This observations further suggests that, compared to (3HS)₂—SiPc, fewer (PDP)₂—SiPc are able to migrate to the P3HT:PC₆₁BM interface and crystalize to participate in the cascade effect, even when increasing the concentration of (PDP)₂—SiPc (FIGS. 4 and 8). It was also observed that under higher (PDP)₂—SiPc loadings (10.6 wt %) the EQE spectrum consistently demonstrated a second peak 720 nm, which is red-shifted from the peak assigned to the SiPc chromophore 700 nm) (FIG. 7A). This second peak could be a result of the broadening of the absorption due to the agglomeration of several (PDP)₂—SiPc molecules present at high loadings, suggesting the formation of (PDP)₂—SiPc clusters.

Further supporting this idea that (3HS)₂—SiPc has an extraordinary tendency to crystallize, crystals of 3HS—BsubPc could not be obtained for X-ray diffraction analysis despite multiple attempts including growth via vapor diffusion (hexanes into DCM or heptanes into benzene), liquid/liquid diffusion by a layering method (DCM to hexanes or benzene to heptane), or slow cooling from hot solvent such as chloroform, dichloromethane or toluene. Notably, single crystals of (3HS)₂—GePc we able to grow, albeit with more difficulty than for (3HS)₂—SiPc. The resulting molecular structure and solid-state arrangement were again analyzed using X-ray diffraction (CCDC deposition number 988975). It was observed that (3HS)₂—GePc has a similar solid state arrangement to that of (3HS)₂—SiPc.

Based on the above data and observations, (3HS)₂—SiPc is a unique additive to a P3HT:PC₆₁BM BHJ OPV device. Not only does it have appropriate frontier molecular orbital energy levels to facilitate cascade electron transfer but it is also likely that when (3HS)₂—SiPc moves to the P3HT:PC₆₁BM interface during deposition (as determined by Honda, et al., Adv. Energy Mater. 2011, 1:588-598) it crystallizes resulting in better charge transport between the P3HT and PC₆₁BM phases. It is possible that the driving force to crystallization of (3HS)₂—SiPc is the reason it moves wholly to the interface. Conversely, the reason 3HS—BsubPc and (PDP)₂—SiPc are not as effective as (3HS)₂—SiPc is because they do not crystallize as easily, or in other words there is a limited driving force for them to crystallize and thus significant portion remain outside the interface between P3HT and PC₆₁BM. These findings represent a possible explanation to why (3HS)₂—SiPc is such a good dye in assisting a P3HT:PC₆₁BM BHJ OPV devices and that the choice of the tri-n-hexylsiloxy substituent is crucial to its performance. Tri-n-hexylsiloxy substituents offer the necessary solubilizing properties while offering ease for crystallization for a silicon phthalocyanine when in the solid state, resulting in favorable dispersion and charge transfer between the P3HT and the PC₆₁BM.

1. A method for making a bulk-heterojunction photoactive layer, positioning an additive at an interface of a bulk-heterojunction photoactive layer, or enhancing the efficiency of a bulk-heterojunction photoactive layer, the method comprising:
(1) obtaining a mixture comprising a solvent, an electron donor material, an electron acceptable material, and an additive solubilized in the solvent, wherein the additive is alkanedithiol, bis(tri-n-hexylsilyl oxide) germanium phthalocyanine, or a combination thereof
(2) heating the mixture;
(3) forming a bulk-heterojunction photoactive layer from the mixture; and
(4) drying the mixture at room temperature to promote crystallization of the additive,
wherein the additive crystals are positioned at an interface between the electron donor material and the electron acceptor material of the bulk-heterojunction photoactive layer.

2. (canceled)

3. The method of claim 1, wherein the additive in step (1) is solubilized in the solvent up to its saturation point or is supersaturated in the solvent.

4. The method of claim 1, wherein the mixture further comprises a nucleation agent to promote crystallization of the additive during step (2).

5. The method of claim 1, wherein the mixture in step (2) is heated to a temperature of 50° C.

6. The method of claim 1, wherein a non-solvent is added to the mixture in step 2 to promote crystallization of the additive.

7. The method of claim 1, wherein the electron donor material and the electron acceptor material is a P3HT:PC₆₁BM blend.

8. The method of claim 1, wherein the electron donor material is poly(trihexylthiophene) (P3HT) or Poly[2-methoxy-5-(2-ethylhexyloxy)-1,4-phenylenevinylene], or a combination thereof.

9. The method of claim 1, wherein the electron acceptor material is [6,6]phenyl-C₆₁-butyric acid methyl ester (PC₆₁BM), [6,6] phenyl-C₇₁-butyric acid methyl ester (PC₇₁BM), or 1′,1″,4′,4″-tetrahydro-di [1,4] methanonaphthaleno [1,2:2′,3′,56,60:2″,3″] [5,6]fullerene-C₆₀(ICBA), or any combination thereof.

10. (canceled)

11. The method of claim 1, wherein the solvent is chlorobenzene, chloroform, dichlorobenzene, dichloromethane, xylenes, tetrahydronaphthalene, toluene, benzene, quinolone, m-cresol, 1,2,4-trimethylbenzene, methylnaphthalene, or di-methylnaphthalene, or any combination thereof.

12. The method of claim 1, wherein the bulk-heterojunction photoactive layer is formed on a substrate.

13. The method of claim 12, wherein the mixture from step (1) is disposed onto a surface of the substrate.

14. (canceled)

15. The method of claim 12, wherein the substrate is an electrode.

16. The method of claim 15, wherein the electrode is transparent or translucent.

17. (canceled)

18. The method of claim 17, wherein the additive is not bis(tri-n-hexylsilyl oxide) silicon phthalocyanine.

19. The method of claim 1, wherein the power conversion efficiency (n_{eff}) of the bulk-heterojunction photoactive is enhanced by the crystallization of the additive at the interface between the electron donor material and the electron acceptor material.

20. The method of claim 1, wherein the short-circuit current (J_{SC}) of the bulk-heterojunction photoactive is enhanced by the crystallization of the additive at the interface between the electron donor material and the electron acceptor material.

21. A photovoltaic cell comprising a bulk-heterojunction photoactive layer prepared by the process of claim 1.

22. The photovoltaic cell of claim 21, comprising a transparent substrate, a transparent electrode, the bulk-heterojunction photo-active layer, and a second electrode, wherein the photoactive layer is disposed between the transparent electrode and the second electrode.

23. (canceled)

24. (canceled)

25. (canceled)

26. The photovoltaic cell of claim 21, wherein the photovoltaic cell is comprised in an organic electronic device.

27. A bulk-heterojunction photoactive layer prepared by the process of claim 1.

28. (canceled)
